(19) United States
(12) Patent Application Publication
(10) Pub. No.: US 2025/0179684 A1
(43) Pub. Date: Jun. 5, 2025

(54) THERMAL STABLE, ONE-DIMENSIONAL HEXAGONAL-PHASE VANADIUM SULFIDE NANOWIRES AND METHODS FOR PREPARING THE SAME

(71) Applicant: City University of Hong Kong, Hong Kong (HK)

(72) Inventors: Hua ZHANG, Hong Kong (HK); Yi REN, Hong Kong (HK)

(21) Appl. No.: 18/523,934

(22) Filed: Nov. 30, 2023

(51) Int. Cl. C30B 25/00; B82Y 40/00; C30B 29/46; C30B 29/62

(52) U.S. Cl. CPC C30B 25/005; B82Y 40/00; C30B 29/46; C30B 29/62

(57) ABSTRACT

The present invention provides a general salt-assisted chemical vapor deposition (SA-CVD) synthetic method for the high-yield preparation of 1D hexagonal-phase MₓV₆S₈(M=K, Rb, Cs) and KₓV₆S_{y}Se_{8-y} nanowires. The resulting nanowires exhibit typical metallic properties, which can be used as a good van der Waals contact for achieving high-performance fermi level pinning free transistors. The present synthesis method allows a more systematic investigation of the intrinsic properties of hexagonal-phase V₆S₈ structures.

### FIELD OF THE INVENTION

The present invention generally relates to at least the fields of materials science, nanomaterial synthesis, chemical synthesis techniques, crystal structure research, and potential applications in catalysis and electronic devices. More specifically, the present invention relates to salt-assisted synthesis of one-dimensional hexagonal-phase vanadium sulfide nanowires.

### BACKGROUND OF THE INVENTION

Over the past decade, transition metal-chalcogenides (TMCs) have garnered significant attention for their potential in applications such as gas sensing, catalysis, optoelectronics, energy storage, and as an ideal platform for fundamental research on layered quantum systems. One-dimensional (1D) TMCs nanowires, such as M₆X₆(M: Mo or W and X: S, Se, or Te) nanowires, have been extensively investigated due to their fascinating crystal structure and the resulting distinctive physical and chemical properties¹⁻⁵. These properties have led to various possible applications, including catalysis (e.g., hydrogen evolution reaction)⁶ and electronics (e.g., van der Waals contact for two-dimensional (2D) semiconductors)⁷⁻⁸.

As a typical type of transition metal chalcogenide, vanadium sulfides have various compositions, including VS, VS₂, V₂S₃, V₃S₄, V₅S₈, and V₆S₈, some of which can crystallize into different phases with distinct physicochemical properties. For instance, V₆S₈ exhibits two polymorphs, monoclinic and hexagonal. However, the majority of studies have predominantly focused on synthesizing VS₂, and the synthesis of other vanadium sulfides, especially V₆S₈, has been rarely reported.

The nonstoichiometric MₓV₆S₈ (M=K, Rb, Cs) crystals crystallize in a hexagonal structure, which is composed of VS₆ octahedra linked together by shared edges and faces, forming large hexagonal channels running parallel to the c-axis⁹⁻¹¹. These channels can accommodate a variety of atoms, including K, Rb, Cs, etc., allowing for the fine-tuning of the electronic configuration of the structure. For instance, Prof. Zheng Chong, et al. reported a flux growth method for the synthesis of BaₓV₆S₈ crystals. Specifically, the BaS, V, S, and KCl powders were mixed in an evacuated quartz ampoule, and then heated the ampoule for 6 days⁹. However, the reaction time throughout the entire synthesis process is too long, which is not conducive to industries that require large-scale production; and Prof. G. A. Wiegers, et al. reported a closed-system gas-solid method for the synthesis of K_{0.2}V₆S₈ crystals. Specifically, the K₂S, V, and S powders were mixed in an evacuated quartz ampoule, and then heated the ampoule at 1200 K for about a week. Besides, the walls of the quartz ampoules were severely destroyed during the reaction process, which makes the synthesis very challenging¹⁰. Although several synthetic strategies have been reported to prepare hexagonal-phase MₓV₆S₈ bulk crystals, including the closed-system gas-solid method and ion exchange method, these methods usually require complex procedures, multiple steps, and a long reaction time of up to one week and can only produce limited types of MₓV₆S₈ crystals with low yield⁹⁻¹¹.

Salt-assisted chemical vapor deposition (SA-CVD) techniques, utilizing salts or molten salts as precursors, offer a robust approach with significant potential for synthesizing 1D materials. These methods effectively lower the melting points of the precursors, enhance vapor pressure, and accelerate growth speed¹²⁻¹⁵. In comparison to conventional CVD methods, SA-CVD methods exhibit distinct advantages in the production of 1D TMC nanowires, resulting in increased yield and improved reproducibility^{4, 16}. Nevertheless, the application of SA-CVD as a universal strategy for synthesizing 1D hexagonal-phase MₓV₆S₈ nanowires remains unexplored. Hence, there is a strong desire to develop a universal method for synthesizing hexagonal-phase MₓV₆S₈ nanowires with a high yield.

### SUMMARY OF THE INVENTION

To address the aforementioned drawbacks, the present invention develops a novel CVD method to synthesize V₆S₈ crystals with specific morphology and crystal phases.

This invention offers a straightforward CVD method for synthesizing one-dimensional (1D) nonstoichiometric hexagonal-phase vanadium sulfide nanowires with high yield, high conductivity and high catalytic activity. In the structure, VS₆ octahedral units are interconnected by sharing faces and edges to form a stable three-dimensional (3D) V₆S₈ network with hexagonal channels parallel to the c-axis. The diameter of the channels is large enough to accommodate different atoms, such as K, Rb, Cs, etc.

In a first aspect, the present invention provides a thermal stable, one dimensional hexagonal-phase MₓV_{y}S_{z} nanowire, where M is potassium (K), rubidium (Rb), or cesium (Cs); x is about 0.2 or 1.12; y is 6; z is 8. The thermal stable, one dimensional hexagonal-phase MₓV_{y}S_{z} nanowire has c-axis-aligned hexagonal channels. The thermal stable, one dimensional hexagonal-phase MₓV_{y}S_{z} nanowire exhibits an unchanged Raman spectrum in a temperature range of 30 to 300° C. Preferably, y is 6 and z is 8.

In accordance with one embodiment, the c-axis-aligned hexagonal channels have diameters in a range of 5 Å to 10 Å.

In accordance with one embodiment, the thermal stable, one dimensional hexagonal-phase MₓV_{y}S_{z} nanowire functions as effective van der Waals contacts for MoS₂-based field-effect transistors, with good ohmic contact, large charge mobility, and reduced Fermi-level pinning effect.

In accordance with one embodiment, the MₓV_{y}S_{z} nanowire has a thickness ranging from 1-15 nm.

In accordance with another embodiment, the MₓV_{y}S_{z} nanowire is K_{0.2}V₆S₈, exhibiting five distinctive Raman peaks recorded at 532 nm, comprising 169.4, 221.5, 326.7, 340.0, and 374.1 cm⁻¹, respectively.

In a second aspect, the present invention provides a thermal stable, one dimensional hexagonal-phase KₓV₆S_{y}Se_{8-y} nanowire, where x is about 0.68 or 1.34; y is 7.02 or 6.79. The thermal stable, one dimensional hexagonal-phase MₓV_{y}S_{z} nanowire has c-axis-aligned hexagonal channels. The thermal stable, one dimensional hexagonal-phase KₓV₆S_{y}Se_{8-y} nanowire exhibits an unchanged Raman spectrum in a temperature range of 30 to 300° C.

In accordance with one embodiment, the c-axis-aligned hexagonal channels have diameters in a range of 5 Å to 10 Å.

In accordance with one embodiment, the thermal stable, one dimensional hexagonal-phase KₓV₆S_{y}Se_{8-y} nanowire functions as effective van der Waals contacts for MoS₂-based field-effect transistors, with good ohmic contact, large charge mobility, and reduced Fermi-level pinning effect.

In accordance with one embodiment, the KₓV₆S_{y}Se_{8-y} nanowire is K_{0.68}V₆S_{7.02}Se_{0.98}, exhibiting five distinctive Raman peaks recorded at 532 nm, comprising 165.2, 221.3, 328.4, 337.9, and 375.7 cm⁻¹, respectively.

In accordance with another embodiment, the KₓV₆S_{y}Se_{8-y} nanowire is K_{1.34}V₆S_{6.79}Se_{1.21}, exhibiting five distinctive Raman peaks recorded at 532 nm, comprising 157.5, 213.6, 328.4, 337.9, and 370.1 cm⁻¹, respectively.

In a third aspect, the present invention provides a salt-assisted method for synthesizing one-dimensional hexagonal-phase vanadium sulfide nanowires on a substrate, including the steps of:
preparing a substrate;
providing a precursor by mixing vanadium (V) and sulfur (S) compounds;
introducing a metal salt to the precursor via a chemical vapor deposition (SA-CVD) method to obtained a mixture;
transferring the mixture to a quartz boat and covering two pieces of fresh-cleaved fluorophlogopite mica substrates on top of loaded mixture;
transferring the quartz boat to the center of a quartz tube, and then introducing Ar and H₂ to provide an optimal synthesis atmosphere;
heating the quartz tube and then cooling the quartz boat down to room temperature; and growing the one dimensional hexagonal-phase MₓV₆S₈ nanowires and KₓV₆S_{y}Se_{8-y} nanowires on the substrate.

In accordance with one embodiment, the ratio between the precursor and the metal salt is in a range of 1:1 to 1:1.5.

In accordance with one embodiment, the step of providing a precursor comprises mixing V₂S₃ powders and S powders.

In accordance with one embodiment, the substrate is a mica substrate.

In accordance with one embodiment, the metal salt is selected from the group consisting of KCl, K₂S, K₂CO₃, KHCO₃, K₂C₂O₄·H₂O, Rb₂CO₃, and Cs₂CO₃.

In accordance with one embodiment, the quartz tube is purged with 500 s.c.c.m for 20 minutes in advance to remove internal air and moisture.

In accordance with one embodiment, the flow rate ratio between the Ar and H₂ is 4:1.

In accordance with one embodiment, the precursor further includes Selenium (Se) compounds.

Compared to existing technologies, the present invention offers the following major advantages:
(1) The developed synthetic strategy employs a highly robust and straightforward salt-assisted CVD method, enabling the large-scale preparation of 1D hexagonal-phase MₓV₆S₈ nanowires with exceptional yield and reproducibility. This method can be readily upscaled through the utilization of larger CVD furnaces, showcasing promising potential for the future electronic industry.
(2) The present invention provides a universal approach for the direct synthesis of a range of 1D MxV6S8 nanowires featuring the same 3D V6S8 network but varying atoms within the hexagonal channels.

### BRIEF DESCRIPTION OF THE DRAWINGS

Embodiments of the present invention are described in more detail hereinafter with reference to the drawings, in which:

FIG. 1A depicts a schematic illustration of hexagonal-phase MₓV₆S₈ structure along the c-axis. FIG. 1B depicts a schematic illustration of a unit cell of the hexagonal-phase MₓV₆S₈ structure. FIG. 1C depicts a three-dimensional (3D) schematic illustration of hexagonal-phase MₓV₆S₈ structure along the c-axis;

FIG. 2 depicts a schematic diagram of the experimental setup used for synthesizing 1D hexagonal-phase MₓV₆S₈ wnanowires;

FIG. 3A and FIG. 3B show optical and SEM images of the as-prepared KₓV₆S₈ nanowires on the mica substrate. The arrows represent three different preferred growth orientations of nanowires;

FIG. 4 shows an AFM height image of the as-prepared KₓV₆S₈ nanowires on the mica substrate;

FIG. 5 depicts XRD pattern of the prepared hexagonal-phase KₓV₆S₈ nanowires;

FIG. 6A and FIG. 6B show low-magnification and high-resolution TEM images of a typical hexagonal-phase KₓV₆S₈ nanowire along the [11̅00] zone axis. FIG. 6C shows the corresponding FFT pattern taken from the HRTEM image in FIG. 6B.

FIG. 6D shows SAED pattern of a typical KₓV₆S₈ nanowire;

FIG. 7A and FIG. 7B show experimental and simulated SAED patterns of hexagonal-phase KxV6S8 structure along the [11̅00] zone axis, showing a good agreement;

FIG. 8A shows a spherical aberration-corrected HAADF-STEM image of the as-prepared KₓV₆S₈ nanowire along the [101̅0] zone axis. FIG. 8B shows a large-area HAADF-STEM image of the as-prepared KₓV₆S₈ nanowire along the [101̅0] zone axis. FIG. 8C shows a simulated STEM image of the as-prepared KₓV₆S₈ nanowire along the [101̅0] zone axis;

FIG. 9A and FIG. 9B show cross-sectional HAADF-STEM images of a KₓV₆S₈ nanowire along the c-axis. The white arrows in FIG. 9B shows the existence of potassium ions in some hexagonal channels. FIG. 9C shows a simulated cross-sectional STEM image of the hexagonal-phase KₓV₆S₈ structure along the c-axis. FIG. 9D depicts an atomic structure model of hexagonal-phase KₓV₆S₈ structure along the c-axis;

FIG. 10A shows a corresponding fast Fourier transform (FFT) pattern taken from the cross-sectional HAADF-STEM image in FIG. 9A. FIG. 10B shows a simulated SAED pattern of the hexagonal-phase KₓV₆S₈ structure along the c-axis;

FIG. 11 shows a dark-field STEM image of the as-prepared KₓV₆S₈ nanowire, and the corresponding elemental mapping images of the KₓV₆S₈ nanowire. EDS characterization of a hexagonal-phase KₓV₆S₈ nanowire under STEM mode is also shown. The extra element signals originate from the Cu TEM grid. Inset: corresponding weight and atomic ratios of V, S, and K elements obtained from the EDS spectrum;

FIG. 12A depicts Raman spectra of the as-prepared hexagonal-phase KₓV₆S₈ nanowire (gray curve) and bare Si/SiO₂ substrate (black curve). FIG. 12B shows an optical image (left) and Raman mapping image (right) of a single KₓV₆S₈ nanowire. FIG. 12C depicts PL spectra of the as-prepared hexagonal-phase KₓV₆S₈ nanowire (gray curve) and bare Si/SiO₂ substrate (black curve);

FIG. 13 shows 0° and 90° between the incident laser polarization (arrow) and the c-axis of the synthesized KₓV₆S₈ nanowire;

FIG. 14A depicts angle-resolved polarized Raman spectra of the synthesized KₓV₆S₈ nanowire measured under 532 nm laser with polarization angle changing from 0° to 180°. FIG. 14B depicts the corresponding hot spot map of Raman spectra under different polarization angles ranging from 0° to 360°;

FIG. 15 depicts polar coordination charts of the Raman peak intensity as a function of polarization angle;

FIG. 16 depicts Raman spectra of the as-prepared KₓV₆S₈ nanowire under different heating temperatures ranging from 30 to 300° C.;

FIG. 17A depicts XPS spectra of V 2p in the as-grown KₓV₆S₈ nanowires.

FIG. 17B depicts XPS spectra of S 2p in the KₓV₆S₈ nanowires. FIG. 17C depicts XPS spectra of K 2p in the KₓV₆S₈ nanowires;

FIG. 18A shows an optical image of the as-prepared KₓV₆S_{y}Se_{8-y} nanowires on the mica substrate by adding 1 mmol of selenium powders to the reaction mixture.

FIG. 18B shows an optical image of the as-prepared KₓV₆S_{y}Se_{8-y} nanowires on the mica substrate by adding 2 mmol of selenium powders to the reaction mixture;

FIG. 19A and FIG. 19B depict Raman spectra of the synthesized hexagonal-phase KₓV₆S_{y}Se_{8-y} nanowire (gray curve) and bare Si/SiO₂ substrate (black curve);

FIG. 20A and FIG. 20B depict PL spectra of the synthesized hexagonal-phase KₓV₆S_{y}Se_{8-y} nanowire (black curve) and bare Si/SiO₂ substrate (grey curve);

FIG. 21A and FIG. 21B show low-magnification and high-resolution TEM images of a typical hexagonal-phase KₓV₆S_{y}Se_{8-y} nanowire synthesized by adding 2 mmol of selenium powders to the reaction mixture. FIG. 21C shows the corresponding FFT pattern taken from the HRTEM image in FIG. 21B. FIG. 21D shows SAED pattern of a typical KₓV₆S_{y}Se_{8-y} nanowire;

FIG. 22 depicts a dark-field STEM image of the as-prepared KₓV₆S_{y}Se_{8-y} nanowire, and the corresponding elemental mapping images of the KₓV₆S_{y}Se_{8-y} nanowire. EDS characterization of a hexagonal-phase KₓV₆S_{y}Se_{8-y} nanowire under STEM mode is also shown. The extra element signals originate from the Cu TEM grid. Inset: corresponding weight and atomic ratios of V, S, Se and K elements obtained from the EDS spectrum;

FIGS. 23A-23C depict optical images of the hexagonal-phase KₓV₆S₈ nanowires, RbₓV₆S₈ nanowires and CsₓV₆S₈ nanowires synthesized with the assistance of different metal salts; and

FIG. 24A shows an optical image of the three-terminal device based on a single KₓV₆S₈ nanowire. FIG. 24B depicts a typical V_{D}S-I_{D}S electrical curve without gate bias. FIG. 24C depicts typical transfer curves of the device under different source-drain biases. FIG. 24D shows an optical image of the MoS₂-based field effect transistors based on asymmetrical electrode contacts consisting of the nanowire contact on one side and the Cr/Au contact on the other side. FIG. 24E depicts typical transfer of the MoS₂-based field effect transistors. FIG. 24F depicts output curves of the MoS₂-based field effect transistors.

### DETAILED DESCRIPTION

The present invention will be described in detail through the following embodiments with appending drawings. It should be understood that the specific embodiments are provided for an illustrative purpose only, and should not be interpreted in a limiting manner. Those skilled in the art will appreciate that the invention described herein is susceptible to variations and modifications other than those specifically described.

The invention includes all such variation and modifications. The invention also includes all of the steps and features referred to or indicated in the specification, individually or collectively, and any and all combinations or any two or more of the steps or features. Other aspects and advantages of the invention will be apparent to those skilled in the art from a review of the ensuing description.

One-dimensional (1D) transition-metal chalcogenides (TMCs) are garnering growing scientific and technological interest, particularly for applications in ultrasmall electronic interconnects and highly active catalysts. Nevertheless, the range of available TMC nanowires is still quite limited, and the synthesis of new 1D TMC nanowires remains a highly challenging endeavor.

Until now, the majority of research efforts have predominantly concentrated on synthesizing VS₂, with limited attention given to other vanadium sulfides, notably V₆S₈, due to the intricate growth conditions. Only a handful of studies have reported the closed-system gas-solid synthesis of the V₆S₈ structure. Nonetheless, the previous gas-solid method typically involves complex procedures, multiple steps, and an extended reaction time of up to one week, rendering the synthesis process intricate and time-consuming. Furthermore, this method cannot be employed as a universal approach for producing various MₓV₆S₈ structures.

In light of this, the present invention introduces a thermal stable, one dimensional hexagonal-phase MₓV_{y}S_{z} nanowire, where M is potassium (K), rubidium (Rb), or cesium (Cs); x is about 0.2 or 1.12; y is 6; z is 8. The thermal stable, one dimensional hexagonal-phase MₓV_{y}S_{z} nanowire has c-axis-aligned hexagonal channels. The thermal stable, one dimensional hexagonal-phase MₓV_{y}S_{z} nanowire exhibits an unchanged Raman spectrum in a temperature range of 30 to 300° C. Preferably, y is 6 and z is 8.

These nanowires serve as effective van der Waals contacts for MoS₂-based field-effect transistors with good ohmic contact, large charge mobility and reduced Fermi-level pinning effect.

The CVD-synthesized hexagonal-phase MₓV₆S₈ structures are promising for superconductivity due to their large c-axis-aligned channels that can accommodate various ions, allowing for precise electronic configuration adjustments and improved superconducting properties.

The present invention also provides a thermal stable, one dimensional hexagonal-phase KₓV₆S_{y}Se_{8-y} nanowire, where x is about 0.68 or 1.34; y is 7.02 or 6.79. The thermal stable, one dimensional hexagonal-phase MₓV_{y}S_{z} nanowire has c-axis-aligned hexagonal channels. The thermal stable, one dimensional hexagonal-phase KₓV₆S_{y}Se_{8-y} nanowire exhibits an unchanged Raman spectrum in a temperature range of 30 to 300° C.

Additionally, the present invention further provides a general salt-assisted chemical vapor deposition (SA-CVD) synthetic method for the high-yield preparation of 1D hexagonal-phase MₓV₆S₈ and KₓV₆S_{y}Se_{8-y} nanowires on the mica substrate. The method includes preparing a substrate; providing a precursor by mixing vanadium (V) and sulfur (S) compounds; introducing a metal salt to the precursor via a chemical vapor deposition (SA-CVD) method to obtained a mixture; transferring the mixture to a quartz boat and covering two pieces of fresh-cleaved fluorophlogopite mica substrates on top of loaded mixture; transferring the quartz boat to the center of a quartz tube, and then introducing Ar and H2 to provide an optimal synthesis atmosphere; heating the quartz tube and then cooling the quartz boat down to room temperature; and growing the one dimensional hexagonal-phase MxV6S8 nanowires and KxV6SySe8-y nanowires on the substrate. The chemical vapor deposition (CVD) method offers a controllable approach to synthesize vanadium chalcogenide crystals with different compositions, sizes, morphologies, and phases by tuning the growth parameters. The present invention introduces, for the first time, the direct CVD growth of V₆S₈ crystals, overcoming the complex and challenging-to-control growth conditions.

Some easily accessible metal salts include, but are not limited to, KHCO₃, KCl, K₂S, K₂CO₃, K₂C₂O₄·H₂O (for synthesizing KₓV₆S₈ nanowires), Rb₂CO₃ (for synthesizing RbₓV₆S₈ nanowires), and Cs₂CO₃ (for synthesizing CsₓV₆S₈ nanowires), can be utilized to synthesize the 1D hexagonal-phase nanowires.

The as-prepared nanowires are single crystalline, which is characterized by X-ray diffraction (XRD), high-resolution transmission electron microscopy (HRTEM), aberration-corrected high-angle annular dark-field (HAADF) scanning transmission electron microscopy (STEM), selected-area electron diffraction (SAED) and Raman spectroscopy.

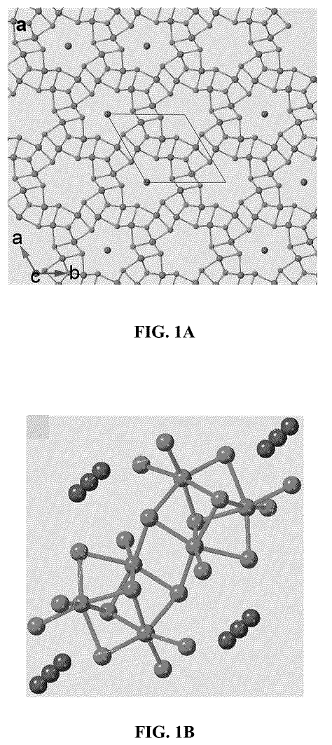

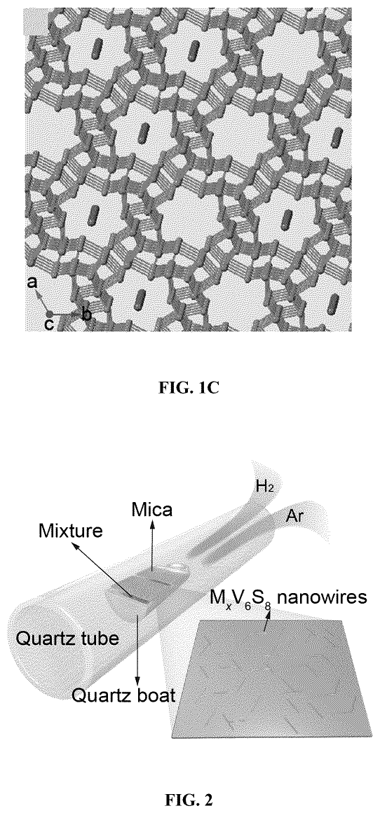

The nonstoichiometric MₓV₆S₈ (M=K, Rb, Cs) crystals crystallize in a hexagonal structure with a space group P6₃/m. Referring to FIG. 1A, the region marked by black lines corresponds to the unit cell of the hexagonal-phase MₓV₆S₈ structure. Six sulfur atoms coordinate with each vanadium atom, and the unit cell is composed of two octahedral trimers connected by sharing an octahedral edge (FIG. 1B). Turning to FIG. 1C, VS₆ octahedra units are joined together by sharing faces and edges to create a stable three-dimensional V₆S₈ network with hexagonal channels parallel to the c-axis⁹⁻¹¹. The diameter of the channels is approximately 6.2 Å, which is sufficiently large to accommodate various atoms, including K, Rb, Cs, and others. Different alkali-metal atoms can form columns within the hexagonal channels.

Despite the significant amount of space available in the channel, the voids are not completely occupied. FIG. 2 depicts a schematic diagram of the salt-assisted CVD method used to synthesize 1D hexagonal-phase MₓV₆S₈ nanowires. More specifically, the commercially available V₂S₃ powders, S powders, and one of the following metal salts including KCl, K₂S, K₂CO₃, KHCO₃, K₂C₂O₄·H₂O (for synthesizing KₓV₆S₈ nanowires), Rb₂CO₃ (for synthesizing RbₓV₆S₈ nanowires), or Cs₂CO₃ (for synthesizing CsₓV₆S₈ nanowires) with a certain molar ratio are mixed and then ground using an agate mortar. After that, the obtained homogenous mixture is covered by two pieces of fresh-cleaved fluorophlogopite mica substrates and then heated under the gas flow of 80% Ar and 20% H₂ at 820-850° C. for 1-10 minutes.

In summary, a straightforward, practical, robust, and versatile SA-CVD strategy has been developed to enable the high-yield synthesis of 1D hexagonal-phase MₓV₆S₈ and KₓV₆S_{y}Se_{8-y} nanowires. Beyond KHCO₃, it has been observed that several other metal salts, including KCl, K₂S, K₂CO₃, K₂C₂O₄·H₂O (for the synthesis of KₓV₆S₈ nanowires), Rb₂CO₃ (for the production of RbₓV₆S₈ nanowires), and Cs₂CO₃ (for the formation of CsₓV₆S₈ nanowires), can also be employed in the synthesis of 1D hexagonal-phase MₓV₆S₈ nanowires. Moreover, this method has also been used to prepare hexagonal-phase alloys, such as KₓV₆S_{y}Se_{8-y} nanowires.

The following examples illustrate the present invention and are not intended to limit the same.

### EXAMPLE

### Example 1—Material and Methods

### Chemicals

Vanadium sulfide (V₂S3, 99.9%), potassium sulfide anhydrous (K₂S, analytical reagent), and potassium chloride (KCl, 99.5%) were purchased from Macklin (China). Potassium carbonate (K₂CO₃, 99%), cesium carbonate (Cs₂CO₃, 99.9%), rubidium carbonate (Rb₂CO₃, 99.8%), and sulfur powder (S, 99.98%) were purchased from Sigma-Aldrich (Germany). Potassium bicarbonate (KHCO₃, 99.9%), potassium oxalate monohydrate (K₂C₂O₄·H₂O, 99.8%), and selenium powder (Se, >99.99%) were purchased from Aladdin (China). Ultra-high purity (99.999%) H₂ and Ar were purchased from Linde HKO Limited (Hong Kong, China). All the chemicals were used as received without any purification.

### Characterization

Optical images were obtained on an optical microscope (Nikon, LV100ND, Japan). Scanning electron microscope (SEM) images were acquired on a scanning electron microscope (Thermo Fisher Scientific, QUATTRO S). The Bruker Icon atomic force microscopy (AFM) system was used to conduct AFM measurements in an atmospheric environment and the AFM height profiles were obtained by an AFM tip (OTESPA-R3, Bruker Nano Inc., USA) under the tapping mode. X-ray diffraction (XRD) patterns were recorded with a Rigaku SmartLab X-ray diffractometer, using a Cu Kα radiation source (λ=1.5406 Å). The samples used for XRD characterization were prepared by transferring the as-prepared hexagonal-phase nanowires from mica substrates to freshly cleaned glass substrates. Transmission electron microscope (TEM) images, high-resolution TEM (HRTEM) images, and selected area electron diffraction (SAED) patterns were taken on a JEOL JEM-2100F (JEOL, Tokyo, Japan) transmission electron microscope. The high-angle annular dark-field scanning TEM (HAADF-STEM) images were captured on a JEOL ARM200F (JEOL, Tokyo, Japan) spherical aberration-corrected transmission electron microscope with a cold field emission gun and an advanced aberration corrector. The acceleration voltage utilized during the operation of all TEMs was 200 kV. Samples for cross-sectional analysis were produced with a focused ion beam (FIB) system (JEOL JIB-4500) and subsequently transferred onto holey carbon-coated Cu grids. Energy dispersive X-ray spectroscopy (EDS) data were collected by using the JEOL JEM-2100F microscope. Raman spectra, Raman mapping images, and photoluminescence (PL) spectra were obtained on a conformal Raman microscope (Renishaw inVia™) with an excitation wavelength of 532 nm and laser spot diameter of about 1 μm. Angle-resolved Raman spectroscopy measurements were carried out by maintaining the polarized laser constant and incrementally rotating the samples by 15°. X-ray photoelectron spectroscopy (XPS) spectra were acquired on the ESCALAB 250Xi (Thermo Fisher Scientific) instrument and the XPS results were calibrated by utilizing the C is peak with a binding energy of 284.8 eV as the reference. The samples used for XPS characterization were prepared by transferring the as-prepared hexagonal-phase nanowires from mica substrates to freshly cleaned Si substrates.

### Example 2—Synthesis of 1D MₓV₆S₈ Nanowires

Synthesis of 1D KₓV₆S₈ Nanowires

1 mmol of V₂S₃ powders, 1.5 mmol of KHCO₃ powders, and 10 mmol of S powders were blended uniformly and then ground for at least 20 minutes utilizing an agate mortar. 20 mg of the obtained mixed powder was transferred to a quartz boat and then two pieces of fresh-cleaved fluorophlogopite mica substrates were precisely covered on the top of the loaded mixture. Then, the quartz boat was transferred to the center of a quartz tube (1 inch in diameter). Before heating, the tube was purged with 500 s.c.c.m (standard cubic centimeter per minute) for 20 minutes to remove the air and moisture inside it, and then with 80 s.c.c.m Ar and 20 s.c.c.m H₂ for 20 minutes to provide an optimal synthesis atmosphere. Subsequently, the tube was inserted into the tube furnace that had been heated to 850° C. and maintained for 6 minutes. After that, the tube furnace was removed from the reaction zone and switched off and the boat was cooled down to room temperature naturally. Finally, the one-dimensional (1D) KₓV₆S₈ nanowires were synthesized on the mica substrate. It is worth noting that the 1D hexagonal-phase KₓV₆S₈ nanowires could also be synthesized by replacing KHCO₃ with other metal salts such as K₂S, KCl, K₂CO₃, and K₂C₂O₄·H₂O while keeping the other growth parameters constant.

Synthesis of 1D RbₓV₆S₈ Nanowires

1 mmol of V₂S₃ powders, 1.6 mmol of Rb₂CO₃ powders, and 5 mmol of S powders were blended uniformly and then ground for at least 20 minutes utilizing an agate mortar. 20 mg of the obtained mixed powder was transferred to a quartz boat and then two pieces of fresh-cleaved fluorophlogopite mica substrates were precisely covered on the top of the loaded mixture. Then, the quartz boat was transferred to the center of a quartz tube (1 inch in diameter). Before heating, the tube was purged with 500 s.c.c.m (standard cubic centimeter per minute) for 20 minutes to remove the air and moisture inside it, and then with 80 s.c.c.m Ar and 20 s.c.c.m H₂ for 20 minutes to provide an optimal synthesis atmosphere. Subsequently, the tube was inserted into the tube furnace that had been heated to 820° C. and maintained for 6 minutes. After that, the tube furnace was removed from the reaction zone and switched off and the boat was cooled down to room temperature naturally. Finally, the 1D RbₓV₆S₈ nanowires were synthesized on the mica substrate.

Synthesis of 1D CsₓV₆S₈ Nanowires

1 mmol of V₂S₃ powders, 1.1 mmol of Cs₂CO₃ powders, and 5 mmol of S powders were blended uniformly and then ground for at least 20 minutes utilizing an agate mortar. 20 mg of the obtained mixed powder was transferred to a quartz boat and then two pieces of fresh-cleaved fluorophlogopite mica substrates were precisely covered on the top of the loaded mixture. Then, the quartz boat was transferred to the center of a quartz tube (1 inch in diameter). Before heating, the tube was purged with 500 s.c.c.m (standard cubic centimeter per minute) for 20 minutes to remove the air and moisture inside it, and then with 80 s.c.c.m Ar and 20 s.c.c.m H₂ for 20 minutes to provide an optimal synthesis atmosphere. Subsequently, the tube was inserted into the tube furnace that had been heated to 850° C. and maintained for 6 minutes. After that, the tube furnace was removed from the reaction zone and switched off and the boat was cooled down to room temperature naturally. Finally, the 1D CsₓV₆S₈ nanowires were synthesized on the mica substrate.

### Example 3—Characterization of 1D MₓV₆S₈ Nanowires

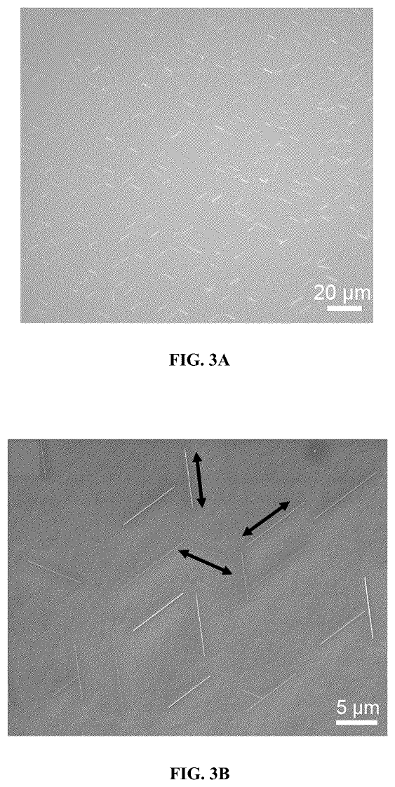

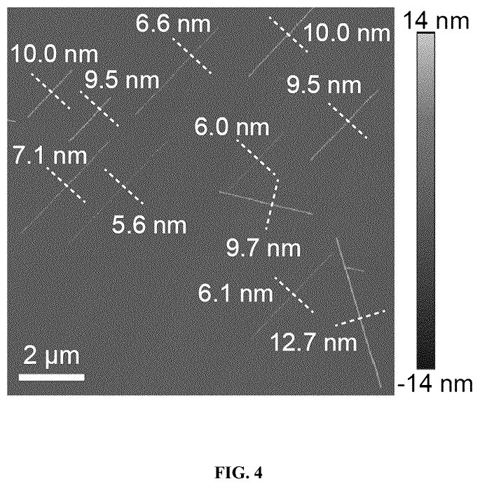

As an example, consider KₓV₆S₈. FIGS. 3A-3B displayed optical and scanning electron microscope (SEM) images of KₓV₆S₈ crystals synthesized with the assistance of KHCO₃ on a mica substrate, demonstrating their high yield and exhibiting a clear 1D nanowire morphology with lengths extending to tens of micrometers. It appeared that the growth of KₓV₆S₈ nanowires was restricted to three main directions, rather than uniform growth in all directions on the surface of the mica substrate. In addition, the atomic force microscopy (AFM) image in FIG. 4 showed that the KₓV₆S₈ nanowires had thicknesses ranging from 5.6 to 12.7 nm, as determined by their height profiles. For instance, the obtained KₓV₆S₈ nanowire had a thickness of 5.6 nm, 6.0 nm, 6.1 nm, 6.6 nm, 7.1 nm, 9.5 nm, 9.7 nm, 10.0 nm, or 12.7 nm.

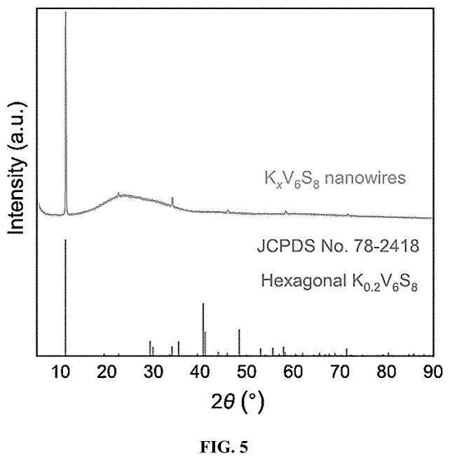

To reveal the crystal structure and crystallinity of the prepared KₓV₆S₈ nanowires, X-ray diffraction (XRD) was performed on the nanowires synthesized with KHCO₃. Referring to FIG. 5, the XRD pattern of hexagonal-phase K_{0.2}V₆S₈ crystals was based on the data of JCPDS No. 78-2418. The obtained XRD pattern exhibited six different diffraction peaks, matching well with the (1010), (2020), (3030), (4040), (5050), and (6060) planes of unconventional hexagonal-phase K_{0.2}V₆S₈ crystals (JCPDS No. 78-2418). However, only the (1010) group planes were discovered. This suggested that the KₓV₆S₈ nanowires grow anisotropically perpendicular to the a-axis.

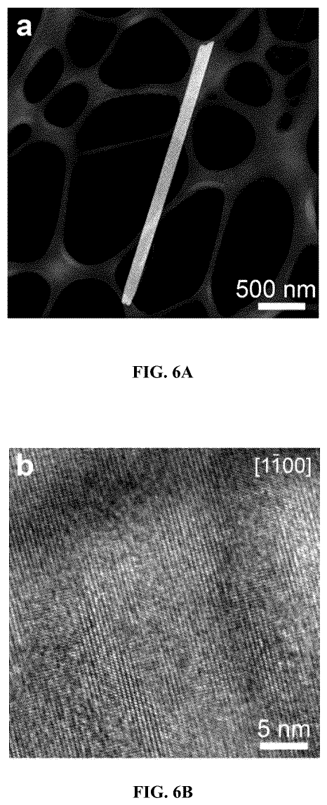

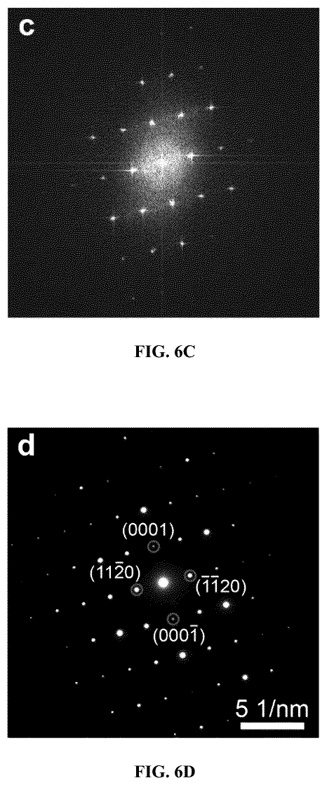

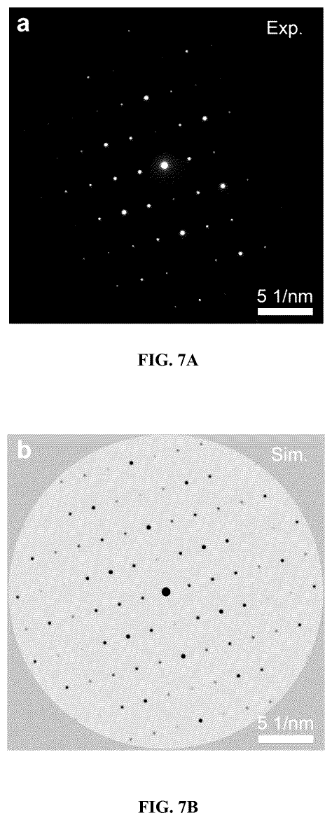

Transmission electron microscopy (TEM) was also performed to investigate the crystal structure and elemental composition of the as-prepared hexagonal KₓV₆S₈ nanowires. FIG. 6A showed a low-magnification TEM image of a typical 1D KₓV₆S₈ nanowire, which was consistent with the morphology depicted in the optical (FIG. 3A) and SEM (FIG. 3B) images. The high-resolution TEM (HRTEM) image in FIG. 6B indicated the excellent crystallinity of the synthesized KₓV₆S₈ nanowire. Correspondingly, the fast Fourier transform (FFT) pattern in FIG. 6C and the selected area electron diffraction (SAED) patterns in FIG. 6D, obtained from different regions of the as-prepared KₓV₆S₈ nanowire along the [11̅00] zone axis, showed only one set of sharp diffraction spots, confirming its single-crystal nature and hexagonal phase structure. Turning to FIG. 7A, the SAED result matched well with the simulated SAED pattern (FIG. 7B) for the hexagonal-phase KₓV₆S₈ structure along the [11̅00] zone axis.

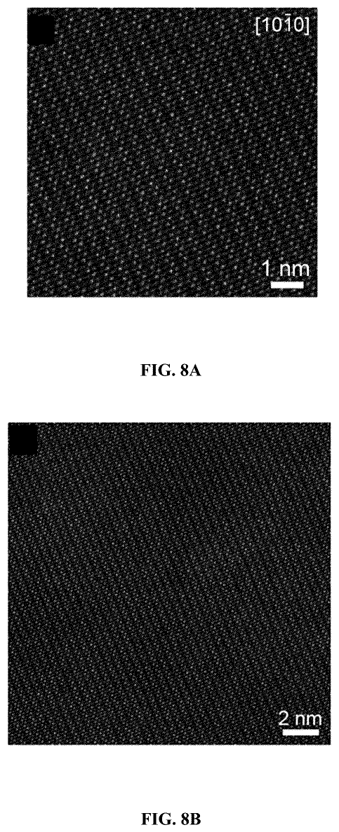

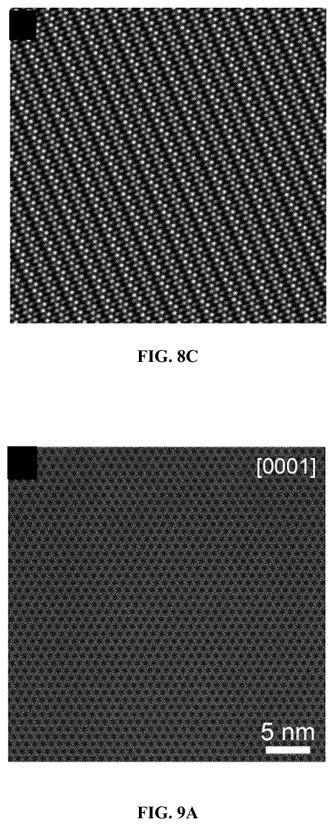

Additionally, spherical aberration-corrected high-angle annular dark-field scanning TEM (HAADF-STEM) was employed to image the atomic structure of the prepared KₓV₆S₈ nanowire. In FIGS. 8A-8B, the STEM images taken along the [11̅00] zone axis revealed the typical atomic arrangement of the hexagonal phase structure, consistent with the simulated STEM image shown in FIG. 8C.

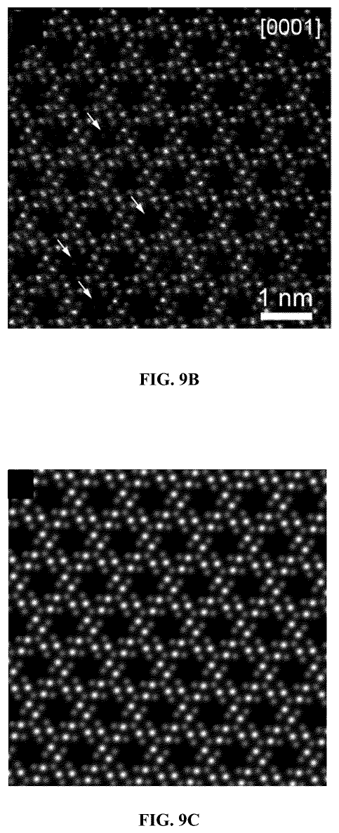

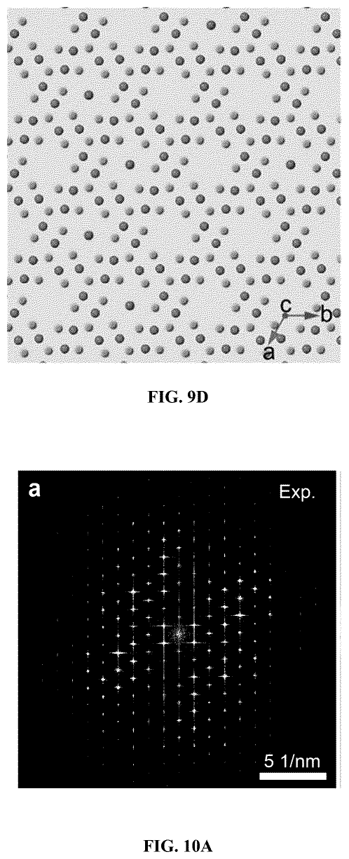

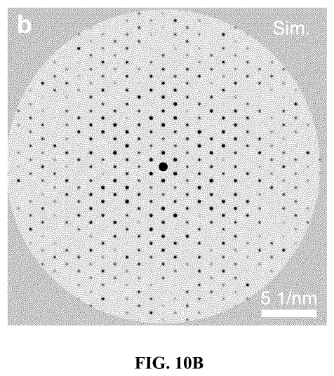

To further elucidate the crystal structure of the 1D KₓV₆S₈ nanowires, focused ion beam (FIB) technique was carried out to cut a KₓV₆S₈ nanowire along the crystal plane perpendicular to the [0001] zone axis. In FIGS. 9A-9B, the cross-sectional HAADF-STEM images clearly revealed the nanowire, comprised of numerous regularly arranged hexagonal channels, growing along the c-axis. The enlarged cross-sectional HAADF-STEM image was shown in FIG. 9B. The result showed that the potassium ions (indicated by white arrows in FIG. 9B) were accommodated within the center of some channels to form columns, surrounded by six sulfur atoms in a trigonally distorted octahedron. These results were consistent with the simulated cross-sectional STEM image (FIG. 9C) and atomic structure model (FIG. 9D) along the [0001] zone axis. In addition, the corresponding FFT pattern (FIG. 10A) of the cross-sectional STEM image (FIG. 9A) was also consistent with the simulated SAED pattern (FIG. 10B), further demonstrating the successful synthesis of hexagonal-phase KₓV₆S₈ nanowires.

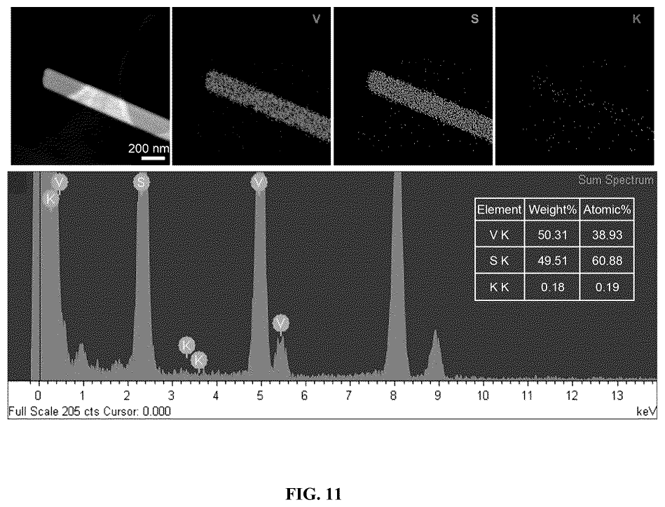

Furthermore, elemental mapping and energy-dispersive X-ray spectroscopy (EDS) spectra, obtained under STEM mode, confirmed the even dispersion of strong V and S signals, along with very weak K signals, with an atomic ratio of approximately 0.2% throughout the KₓV₆S₈ nanowire (FIG. 11).

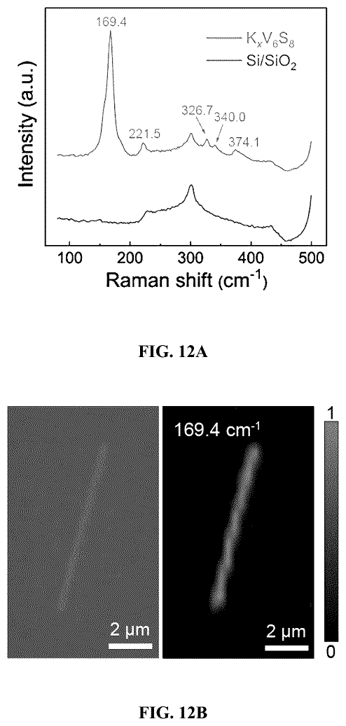

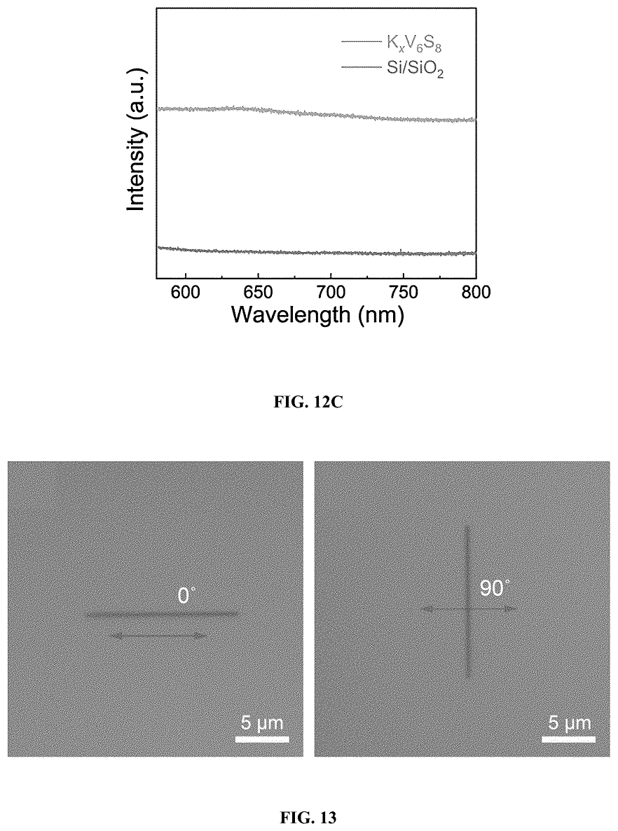

Referring to FIG. 12A, the Raman spectrum (recorded at 532 nm) of the KₓV₆S₈ nanowire displayed five distinctive Raman peaks located at 169.4, 221.5, 326.7, 340.0, and 374.1 cm⁻¹, respectively, which are different from those in previously reported vanadium sulfides¹⁷⁻¹⁹. The Raman mapping image (FIG. 12B) of a single KₓV₆S₈ nanowire exhibited uniform Raman signals, indicating its uniform chemical composition and crystal structure, as well as the high quality of the as-prepared 1D KₓV₆S₈ nanowires.

Furthermore, the photoluminescence (PL) spectra of the synthesized KₓV₆S₈ nanowire and the bare Si/SiO₂ substrate were depicted in FIG. 12C. The photoluminescence PL spectra exhibited the PL quenching phenomenon without obvious absorption peaks, indicating the metallic property of 1D KₓV₆S₈ nanowires.

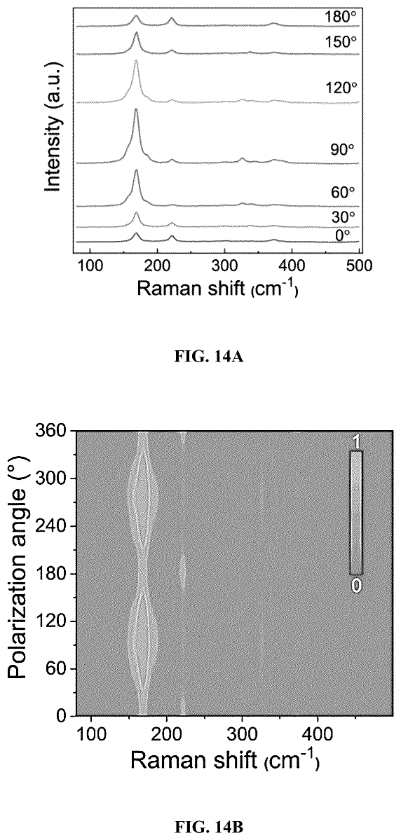

Moreover, angle-resolved polarized Raman spectroscopy (ARPRS) was conducted to investigate the anisotropic phonon vibration and crystal orientation of the as-prepared KₓV₆S₈ nanowire²⁰⁻²¹. During the test process, 0° and 90° indicated that the laser's polarization aligned parallel and perpendicular to the c-axis of the synthesized KₓV₆S₈ nanowire, respectively (FIG. 13). The polarized Raman spectra from 0° to 180° and the corresponding hot spot map were displayed in FIGS. 14A-14B, revealing that the peak intensity of all five Raman modes exhibited periodic variations when parallel polarization configurations were applied. This observation indicated the structural anisotropy of the as-prepared KₓV₆S₈ nanowire.

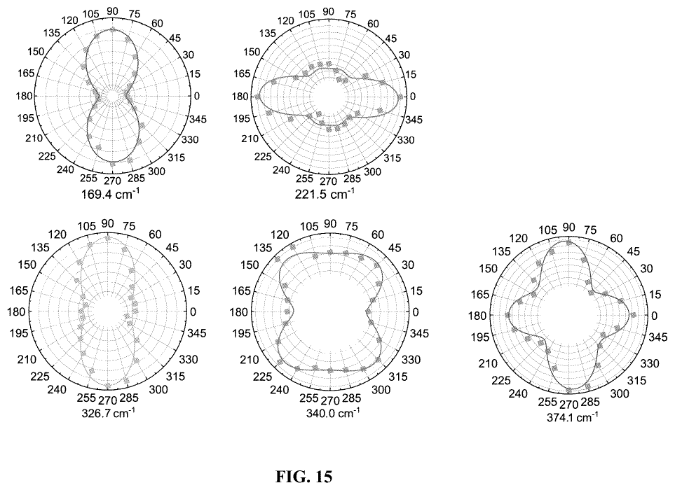

To further investigate the correlation between the Raman peaks and polarization angle, polar coordinate charts for all five Raman modes (Raman peaks located at 169.4, 221.5, 326.7, 340.0, and 374.1 cm⁻¹) were also depicted in FIG. 15. The intensities of the Raman peaks at 221.5, 340.0, and 374.1 cm⁻¹ displayed four angles of maximum intensity. In contrast, the intensities of the Raman modes at 169.4 and 326.7 cm⁻¹ exhibited a 180° period, with minimum Raman intensities at polarization angles of 0° and 180°. This observation aligns well with the c-axis of the synthesized KₓV₆S₈ nanowire, allowing it to be used for determining its crystalline orientation.

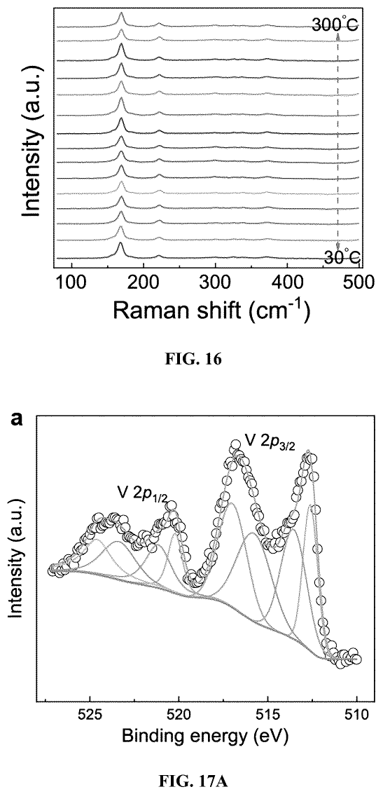

Furthermore, temperature-dependent Raman spectra was performed to reveal the thermal stability of the synthesized hexagonal-phase KₓV₆S₈ nanowire. As shown in FIG. 16, the Raman spectra remained unchanged in the temperature range of 30 to 300° C., indicating its remarkable stability at elevated temperatures. Such exceptional thermal stability offered significant advantages in various applications, particularly in device fabrication for exploring the electrical properties of the as-grown KₓV₆S₈ nanowires.

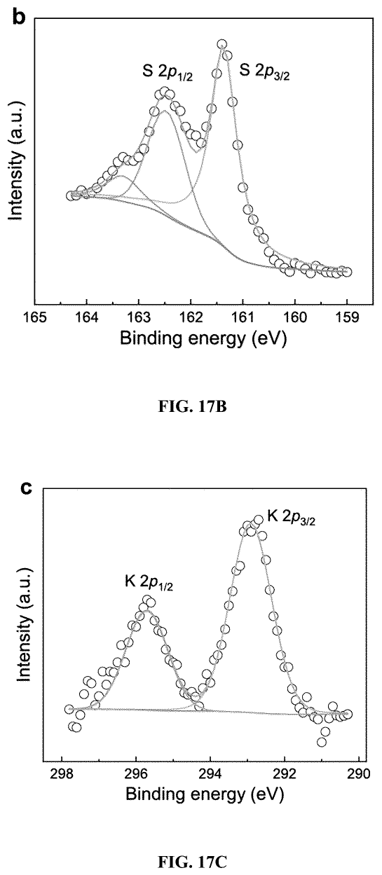

Furthermore, X-ray photoelectron spectroscopy (XPS) measurements were conducted on the as-prepared KₓV₆S₈ nanowires to investigate the electronic states of the elements (FIGS. 17A-17C). In FIG. 17A, as shown in the V 2p spectra, both V²⁺ and V³⁺ coexisted in the KₓV₆S₈ nanowires, demonstrating the formation of V-S bonds. The V 2p_{1/2} and V 2p_{3/2} located at 520.2 and 512.6 eV corresponded to the unreacted V element while the V 2p_{1/2} and V 2p_{3/2} located at 524.6 and 517.0 eV were attributed to the oxidization of the as-grown KₓV₆S₈ nanowires. In FIG. 17B, as shown in the S 2p spectra, the peaks located at 161.4 and 162.5 eV were the S 2p_{3/2} and S 2p_{1/2} while the peak located at high binding energy was induced by the oxidized nanowires, which was consistent with the XPS spectra of V. In FIG. 17C, as shown in the K 2p spectra, the K 2p_{1/2} and K 2p_{3/2} located at 295.7 and 292.9 eV confirmed the presence of potassium ions in the as-prepared KₓV₆S₈ nanowires. The above XPS results agreed well with the previous reports on vanadium sulfides^{11,17,22}.

### Example 4—Synthesis of Hexagonal-Phase KₓV₆S_{y}S_{8-y} Nanowires

1 mmol of V₂S₃ powders, 1.5 mmol of KHCO₃ powders, 10 mmol of S powders, and 1 or 2 mmol of Se powders were blended uniformly and then ground for at least 20 minutes utilizing an agate mortar. 20 mg of the obtained mixed powder was transferred to a quartz boat and then two pieces of fresh-cleaved fluorophlogopite mica substrates were precisely covered on the top of the loaded mixture. Then, the quartz boat was transferred to the center of a quartz tube (1 inch in diameter). Before heating, the tube was purged with 500 s.c.c.m for 20 minutes to remove the air and moisture inside it, and then with 80 s.c.c.m Ar and 20 s.c.c.m H₂ for 20 minutes to provide an optimal synthesis atmosphere. Subsequently, the tube was inserted into the tube furnace that had been heated to 850° C. and maintained for 6 minutes. After that, the tube furnace was removed from the reaction zone and switched off and the boat was cooled down to room temperature naturally. Finally, the 1D KₓV₆S_{y}Se_{8-y} nanowires were synthesized on the mica substrate. It is worth noting that the 1D hexagonal-phase KₓV₆S_{y}Se_{8-y} nanowires could also be synthesized by replacing KHCO₃ with other metal salts such as K₂S, KCl, K₂CO₃, and K₂C₂O₄·H₂O while keeping the other growth parameters constant.

### Example 5—Characterization of Hexagonal-Phase KₓV₆S_{y}Se_{8-y} Nanowires

By adding 1 or 2 mmol of Se powders to the reaction mixture, 1D hexagonal-phase KₓV₆S_{y}Se_{8-y} nanowires with different chemical compositions (sulfur-to-selenium ratios) could be easily synthesized.

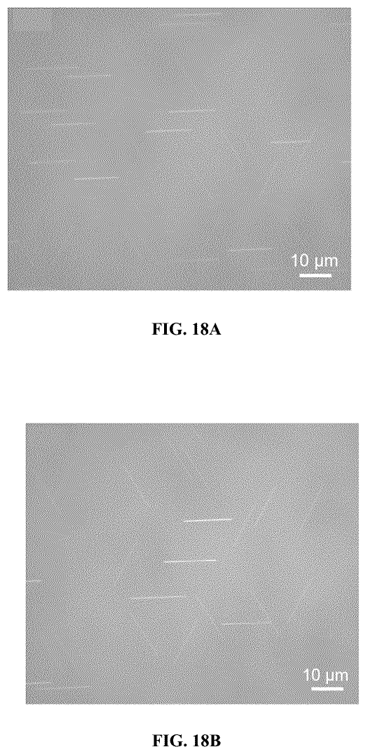

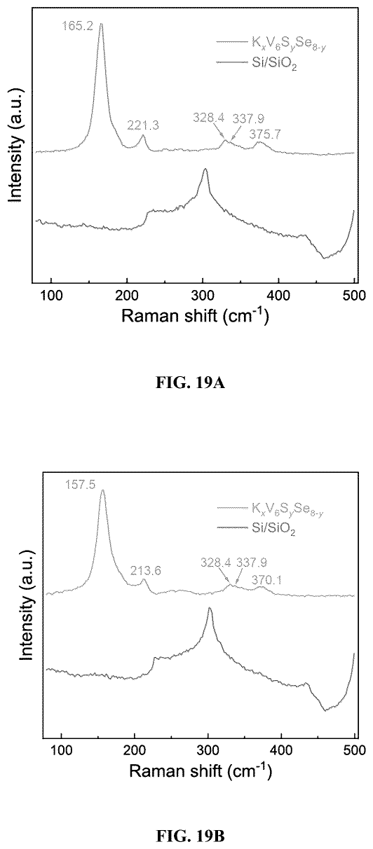

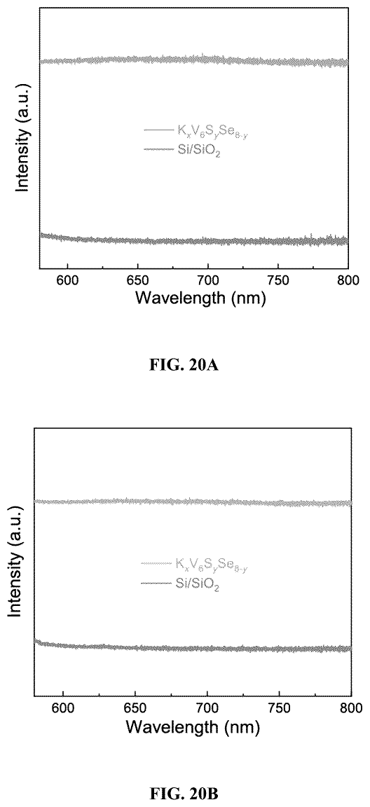

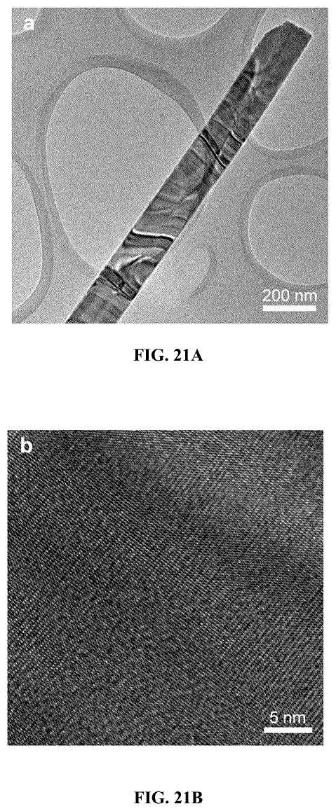

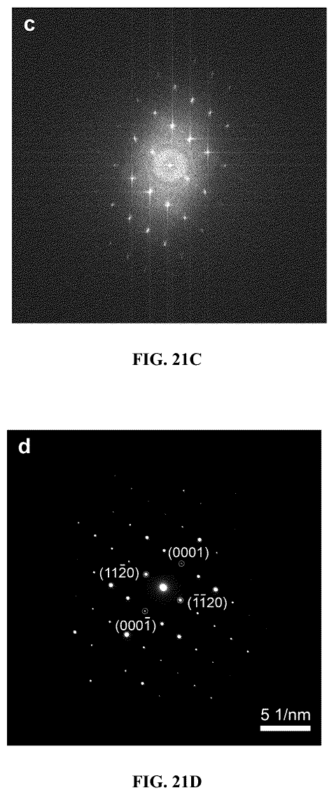

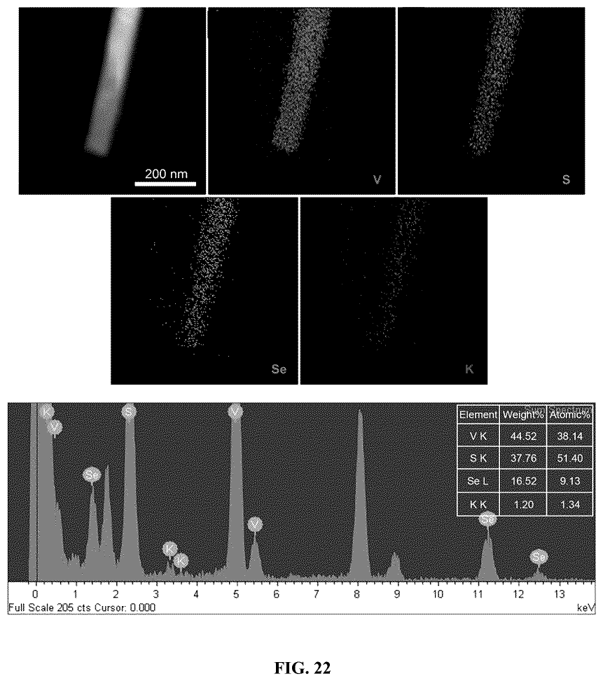

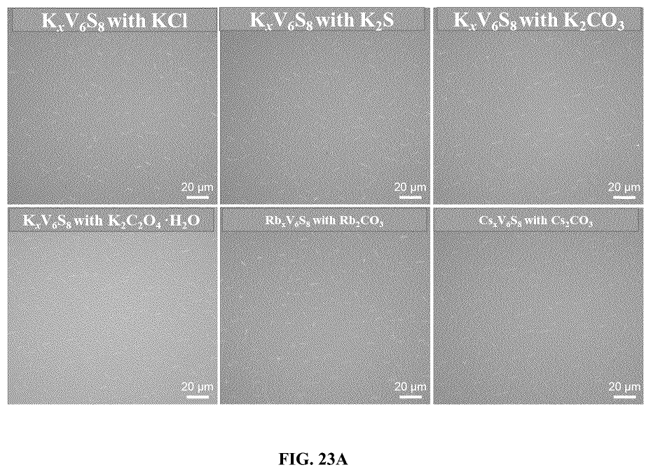

As shown in FIGS. 18A-18B, two as-grown hexagonal-phase KₓV₆S_{y}Se_{8-y} alloys presented a 1D nanowire morphology with lengths of tens of micrometers, similar to the KₓV₆S₈ nanowires (FIGS. 3A-3B). The Raman spectra of the synthesized KₓV₆S_{y}Se_{8-y} nanowires shown in FIG. 19A-19B and the PL spectra of the synthesized KₓV₆S_{y}Se_{8-y} nanowires shown in FIGS. 20A-20B also exhibited similar Raman peaks and PL quenching phenomena, indicating their metallic nature. The crystal structure of the KₓV₆S_{y}Se_{8-y} nanowire was further characterized by HRTEM and SAED (FIG. 21A-21D), demonstrating good crystallinity and hexagonal phase structure. Furthermore, the elemental mapping images and EDS characterizations of the KₓV₆S_{y}Se_{8-y} nanowires showed the even distribution of V, S, Se, and K signals throughout the entire nanowire (FIG. 22).

More impressively, in addition to KHCO₃, it was observed that several other metal salts, such as KCl, K₂S, K₂CO₃, K₂C₂O₄·H2O (for synthesizing KₓV₆S₈ nanowires), Rb₂CO₃ (for synthesizing RbₓV₆S₈ nanowires), and Cs₂CO₃ (for synthesizing CsₓV₆S₈ nanowires), could also be utilized to synthesize the 1D hexagonal-phase MₓV₆S₈ nanowires. This indicated the generality of the salt-assisted CVD method. Such method could adjust the types of atoms in the hexagonal channels, offering the opportunity to tune the electronic configuration of the structure and manipulate its physicochemical properties.

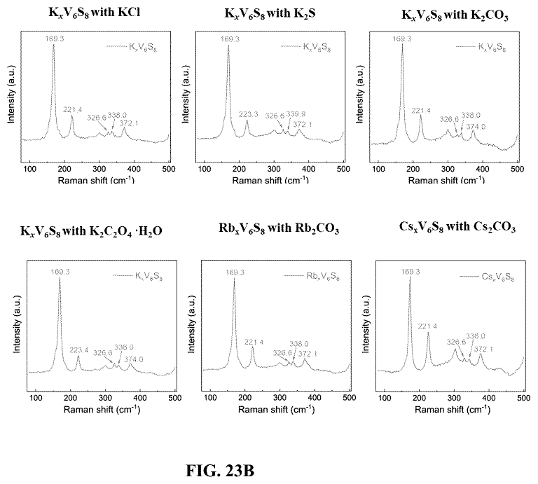

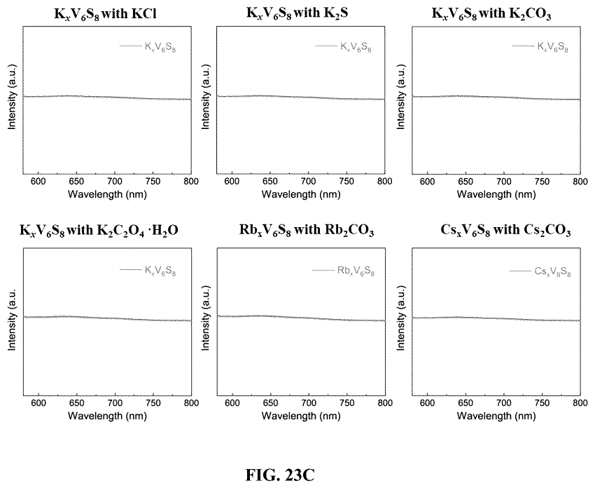

Referring to FIG. 23A, with the assistance of different metal salts, the as-prepared MₓV₆S₈ crystals all exhibited 1D nanowire morphology, unique characteristic Raman spectra (FIG. 23B), and complete PL quenching phenomena (FIG. 23C), which agreed well with the KₓV₆S₈ nanowires synthesized with the assistance of KHCO₃. Moreover, the as-grown RbₓV₆S₈ and CsₓV₆S₈ nanowires had also been characterized by HRTEM, SAED, elemental mapping, and EDS, clearly showing their hexagonal phase structure and uniformly distributed elemental signals in the nanowires.

### EXAMPLE 6-Transfer of Hexagonal-Phase MₓV₆S₈ and KₓV₆S_{y}Se_{8-y} Nanowires

The as-grown nanowires were transferred based on a previously reported poly(methyl methacrylate) (PMMA)-assisted method with slight modifications. First, the fluorophlogopite mica substrate with the as-prepared hexagonal-phase nanowires was spin-coated with PMMA (PMMA 495, A8, Microchem) at 3000 revolutions per minute (r.p.m.) for 50 s, followed by baking at 75° C. for 18 min. After removing the edge of the mica substrate, nanowires coated with PMMA were easily peeled off from the substrate by using deionized water. Subsequently, the floating PMMA film with nanowires was transferred onto a clean Si/SiO₂ substrate, followed by heating at 90° C. for 30 min to increase the adhesion between the PMMA film and the Si/SiO₂ substrate. After that, PMMA was eliminated by immersing the Si/SiO₂ substrate in acetone for 10 hours. Finally, the Si/SiO₂ substrate was dried using nitrogen gas, and the synthesized hexagonal-phase nanowires were left on the Si/SiO₂ substrate.

### Example 7—Device Fabrication and Measurement

For the fabrication of the three-terminal device based on a single KₓV₆S₈ nanowire, at first, the transfer of 1D KₓV₆S₈ nanowires was performed according to the PMMA-assisted wet transfer method. After the 1D KₓV₆S₈ nanowires were transferred from mica to the Si/50 nm SiO₂ substrate, drain and source electrodes were fabricated on the nanowire by the standard electron-beam lithography processing. Then 8 nm of Cr and 70 nm of Au were thermally evaporated as electrodes and followed by a lift-off process.

For the fabrication of MoS₂-based field effect transistors based on asymmetrical electrode contacts consisting of the nanowire contact on one side and the Cr/Au contact on the other side, at first, monolayer MoS₂ was grown at 850° C. for 30 min onto Si/300 nm SiO₂ substrates by the oxygen-assisted CVD method with the 500/1 s.c.c.m Ar/O₂ mixed flow. The transfer of 1D KₓV₆S₈ nanowires was performed according to the PMMA-assisted wet transfer method. After the 1D KₓV₆S₈ nanowires were transferred from mica to the sacrificial Si/50 nm SiO₂ substrate, the polypropylene carbonate (PPC) layer was spin coated on the silicon substrate with a speed of 3000 rpm and was baked at 60° C. for 2 min. These nanowires were mechanically peeled (pick-up) in DI water and released (drop-down) to the target substrate by a PPC-coated poly(dimethylsiloxane) (PDMS) block mounted on a glass slide via the mechanical aligner under an optical microscope. Before the PPC removal, the transferred sample covered by the PPC film was baked at 150° C. for >30 min to improve the vdWs coupling strength of metal-semiconductor contacts. Then drain and source electrodes were fabricated on the device by the standard electron-beam lithography processing. And 8 nm of Cr and 70 nm of Au were thermally evaporated as electrodes and followed by a lift-off process.

The electrical properties of these devices were measured in the Probe Station by Keysight B1500A Semiconductor Device Parameter Analyzer.

### Example 8—Electrical Properties of 1D KₓV₆S₈ Nanowires

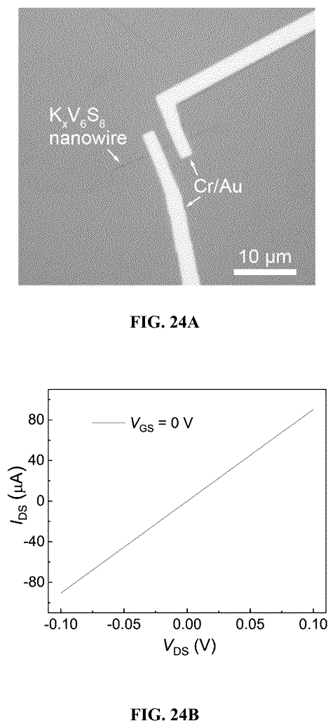

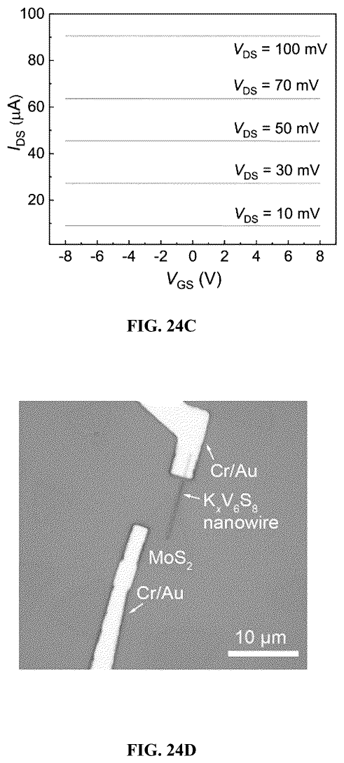

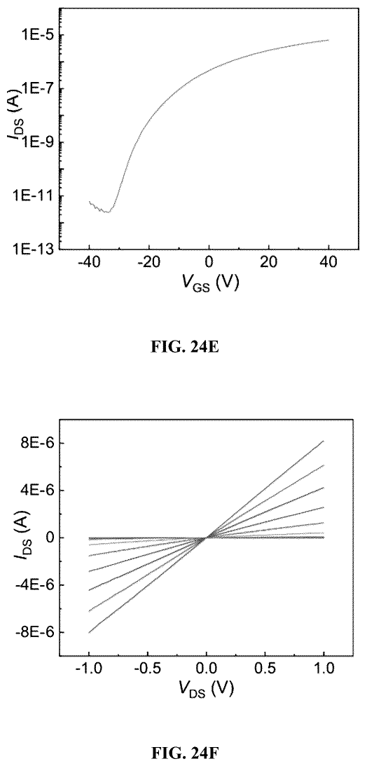

As shown in FIG. 24A, a three-terminal device based on a single KₓV₆S₈ nanowire was fabricated. In the device, Si served as the substrate, a 50 nm SiO₂ layer acted as the dielectric, a KₓV6S8 nanowire functioned as the semiconducting channel, and Cr/Au were used as the source-drain electrodes and gate electrode, respectively.

The AFM image of the device revealed that the thickness of the 1D KₓV₆S₈ nanowire was approximately 12 nm. The electrical curve without the gate bias (FIG. 24B) displayed a linear V_{DS}-I_{DS} relationship and nearly ideal ohmic contact. Besides, the transfer curve of the device (FIG. 24C) exhibited weak gate-tunable conductance without electrical switching behaviors²³. These results demonstrated the metallic nature of 1D KₓV₆S₈ nanowires, which was in agreement with the photoluminescence characterization results.

Furthermore, MoS₂-based field-effect transistors were fabricated using asymmetrical electrode contacts, with the nanowire contact on one side and the Cr/Au contact on the other side, as shown in FIG. 24D. Surprisingly, the devices exhibited good n-type semiconducting behavior with an on/off ratio of 10⁶ (FIG. 24E), and the output curves (FIG. 24F) showed that the Schottky barriers of the contacts on both sides were basically the same, indicating that the synthesized nanowires may be a good van der Waals contact for achieving high-performance fermi level pinning free transistors²⁴⁻²⁶.

### Definitions

Throughout this specification, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. Patent law; e.g., they allow for elements not explicitly recited, but exclude elements that are found in the prior art or that affect a basic or novel characteristic of the present invention.

Furthermore, throughout the specification and claims, unless the context requires otherwise, the word “include” or variations such as “includes” or “including”, will be understood to imply the inclusion of a stated integer or group of integers but not the exclusion of any other integer or group of integers.

References in the specification to “one embodiment”, “an embodiment”, “an example embodiment”, etc., indicate that the embodiment described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

Other definitions for selected terms used herein may be found within the detailed description of the present invention and apply throughout. Unless otherwise defined, all other technical terms used herein have the same meaning as commonly understood to one of ordinary skill in the art to which the present invention belongs.

It will be appreciated by those skilled in the art, in view of these teachings, that alternative embodiments may be implemented without undue experimentation or deviation from the spirit or scope of the invention, as set forth in the appended claims. This invention is to be limited only by the following claims, which include all such embodiments and modifications when viewed in conjunction with the above specification and accompanying drawings.

### INDUSTRIAL APPLICABILITY

The present invention offers a robust and straightforward CVD method for synthesizing highly conductive 1D metallic hexagonal-phase MₓV₆S₈ nanowires with high yield. These nanowires are utilized as excellent van der Waals contacts in MoS₂-based field-effect transistors, resulting in good ohmic contact, significant charge mobility, and reduced Fermi-level pinning. This synthetic strategy exhibits promising potential for electronic applications. Moreover, CVD-synthesized hexagonal-phase MxV₆S₈ structures are promising candidates for superconductivity due to their large channels aligned with the c-axis. These channels can host various ions, allowing for precise electronic structure adjustments and the enhancement of their superconducting properties.

Due to the high conductivity of MₓV₆S₈ nanowires, the as-prepared nanowires can also function as electrode materials for supercapacitors and batteries.

### REFERENCES: THE DISCLOSURES OF THE FOLLOWING REFERENCES ARE INCORPORATED BY REFERENCE

ADDIN EN.REFLIST
[1]S. Iijima, Nature 1991, 354, 56.
[2]R. S. Wagner, W. C. Ellis, Appl. Phys. Lett. 2004, 4, 89.
[3]J. Lin, O. Cretu, W. Zhou, K. Suenaga, D. Prasai, K. I. Bolotin, N. T. Cuong, M. Otani, S. Okada, A. R. Lupini, J.-C. Idrobo, D. Caudel, A. Burger, N. J. Ghimire, J. Yan, D. G. Mandrus, S. J. Pennycook, S. T. Pantelides, Nat. Nanotechnol. 2014, 9,436.
[4]H. E. Lim, Y. Nakanishi, Z. Liu, J. Pu, M. Maruyama, T. Endo, C. Ando, H. Shimizu, K. Yanagi, S. Okada, T. Takenobu, Y. Miyata, Nano Lett. 2021, 21, 243.
[5]Y. Yoo, J. S. Jeong, R. Ma, S. J. Koester, J. E. Johns, Chem. Mater. 2020, 32, 9650.
[6]D. Voiry, H. S. Shin, K. P. Loh, M. Chhowalla, Nat. Rev. Chem. 2018, 2, 0105.
[7]L. Venkataraman, C. M. Lieber, Phys. Rev. Lett. 1999, 83, 5334.
[8]Y. Chen, Z. Lai, X. Zhang, Z. Fan, Q. He, C. Tan, H. Zhang, Nat. Rev. Chem. 2020, 4, 243.
[9]O. Fuentes, H.-H. Wang, B. H. Ward, J. Zhang, D. M. Proserpio, F. Calvagna, C. E. Check, K. C. Lobring, C. Zheng, Chem. Mater. 2001, 13, 3051.
[10] K. D. Bronsema, G. A. Wiegers, Mat. Res. Bull. 1987, 22, 1073.
[11] W. Bensch, J. Koy, M. Wesemann, J. Alloys Compd. 1992, 178, 193.
[12]S. Li, S. Wang, D.-M. Tang, W. Zhao, H. Xu, L. Chu, Y. Bando, D. Golberg, G. Eda, Appl. Mater. Today 2015, 1, 60.
[13]J. Zhou, J. Lin, X. Huang, Y. Zhou, Y. Chen, J. Xia, H. Wang, Y. Xie, H. Yu, J. Lei, D. Wu, F. Liu, Q. Fu, Q. Zeng, C.-H. Hsu, C. Yang, L. Lu, T. Yu, Z. Shen, H. Lin, B. I. Yakobson, Q. Liu, K. Suenaga, G. Liu, Z. Liu, Nature 2018, 556, 355.
[14] B. Qin, M. Z. Saeed, Q. Li, M. Zhu, Y. Feng, Z. Zhou, J. Fang, M. Hossain, Z. Zhang, Y. Zhou, Y. Huangfu, R. Song, J. Tang, B. Li, J. Liu, D. Wang, K. He, H. Zhang, R. Wu, B. Zhao, J. Li, L. Liao, Z. Wei, B. Li, X. Duan, X. Duan, Nat. Commun. 2023, 14, 304.
[15]J. You, J. Pan, S.-L. Shang, X. Xu, Z. Liu, J. Li, H. Liu, T. Kang, M. Xu, S. Li, D. Kong, W. Wang, Z. Gao, X. Zhou, T. Zhai, Z.-K. Liu, J.-K. Kim, Z. Luo, Nano Lett. 2022, 22, 10167.
[16]Z. Lai, Y. Yao, S. Li, L. Ma, Q. Zhang, Y. Ge, W. Zhai, B. Chi, B. Chen, L. Li, L. Wang, Z. Zheng, L. Gu, Y. Du, H. Zhang, Adv. Mater. 2022, 34, 2201194.
[17]J. Zhou, W. Zhang, Y.-C. Lin, J. Cao, Y. Zhou, W. Jiang, H. Du, B. Tang, J. Shi, B. Jiang, X. Cao, B. Lin, Q. Fu, C. Zhu, W. Guo, Y. Huang, Y. Yao, S. S. P. Parkin, J. Zhou, Y. Gao, Y. Wang, Y. Hou, Y. Yao, K. Suenaga, X. Wu, Z. Liu, Nature 2022, 609, 46.
[18]Q. Ji, C. Li, J. Wang, J. Niu, Y. Gong, Z. Zhang, Q. Fang, Y. Zhang, J. Shi, L. Liao, X. Wu, L. Gu, Z. Liu, Y. Zhang, Nano Lett. 2017, 17, 4908.
[19]J. Yuan, J. Wu, W. J. Hardy, P. Loya, M. Lou, Y. Yang, S. Najmaei, M. Jiang, F. Qin, K. Keyshar, H. Ji, W. Gao, J. Bao, J. Kono, D. Natelson, P. M. Ajayan, J. Lou, Adv. Mater. 2015, 27, 5605.
[20]Y. Li, S. Wang, J. Hong, N. Zhang, X. Wei, T. Zhu, Y. Zhang, Z. Xu, K. Liu, M. Jiang, H. Xu, Small 2023, n/a, 2302623.
[21]Y. Lu, W. Yu, Y. Zhang, J. Zhang, C. Chen, Y. Dai, X. Hou, Z. Dong, L. Yang, L. Fang, L. Huang, S. Lin, J. Wang, J. Wang, J. Li, K. Zhang, Small 2023, n/a, 2303903.
[22]W. Bensch, J. Abart, E. Amberger, Solid State Commun. 1986, 58, 631.
[23]Z. Lai, Q. He, T. H. Tran, D. V. M. Repaka, D.-D. Zhou, Y. Sun, S. Xi, Y. Li, A. Chaturvedi, C. Tan, B. Chen, G.-H. Nam, B. Li, C. Ling, W. Zhai, Z. Shi, D. Hu, V. Sharma, Z. Hu, Y. Chen, Z. Zhang, Y. Yu, X. Renshaw Wang, R. V. Ramanujan, Y. Ma, K. Hippalgaonkar, H. Zhang, Nat. Mater. 2021, 20, 1113.
[24]X. Zhang, Z. Kang, L. Gao, B. Liu, H. Yu, Q. Liao, Z. Zhang, Y. Zhang, Adv. Mater. 2021, 33, 2104935.
[25]Y. Wang, J. C. Kim, R. J. Wu, J. Martinez, X. Song, J. Yang, F. Zhao, A. Mkhoyan, H. Y. Jeong, M. Chhowalla, Nature 2019, 568, 70.
[26]X. Zhang, H. Yu, W. Tang, X. Wei, L. Gao, M. Hong, Q. Liao, Z. Kang, Z. Zhang, Y. Zhang, Adv. Mater. 2022, 34, 2109521.

What is claimed is:

1. A thermal stable, one dimensional hexagonal-phase MₓV_{y}S_{z} nanowire, wherein M=K, Rb, Cs;
x=0.2 or 1.12;
y=6;
z=8,
wherein the thermal stable, one dimensional hexagonal-phase MₓV_{y}S_{z} nanowire has c-axis-aligned hexagonal channels, and wherein the thermal stable, one dimensional hexagonal-phase MₓV_{y}S_{z} nanowire exhibits an unchanged Raman spectrum in a temperature range of 30 to 300° C.

2. The thermal stable, one dimensional hexagonal-phase MₓV_{y}S_{z} nanowire of claim 1, wherein y=6 and z=8.

3. The thermal stable, one dimensional hexagonal-phase MₓV_{y}S_{z} nanowire of claim 1, wherein the c-axis-aligned hexagonal channels have diameters in a range of 5 Å to 10 Å.

4. The thermal stable, one dimensional hexagonal-phase MₓV_{y}S_{z} nanowire of claim 1, wherein the thermal stable, one dimensional hexagonal-phase MₓV_{y}S_{z} nanowire functions as effective van der Waals contacts for MoS₂-based field-effect transistors, with good ohmic contact, large charge mobility, and reduced Fermi-level pinning effect.

5. The thermal stable, one dimensional hexagonal-phase MₓV_{y}S_{z} nanowire of claim 1, wherein the MₓV_{y}S_{z} nanowire has a thickness ranging from 1-15 nm.

6. The thermal stable, one dimensional hexagonal-phase MₓV_{y}S_{z} nanowire of claim 1, wherein the MₓV_{y}S_{z} nanowire is K_{0.2}V₆S₈, exhibiting five distinctive Raman peaks recorded at 532 nm, comprising 169.4, 221.5, 326.7, 340.0, and 374.1 cm⁻¹, respectively.

7. A thermal stable, one dimensional hexagonal-phase KₓV₆S_{y}Se_{8-y} nanowire, wherein
x=0.68 or 1.34;
y=7.02 or 6.79,
wherein the thermal stable, one dimensional hexagonal-phase MₓV_{y}S_{z} nanowire has c-axis-aligned hexagonal channels, and wherein the thermal stable, one dimensional hexagonal-phase KₓV₆S_{y}Se_{8-y} nanowire exhibits an unchanged Raman spectrum in a temperature range of 30 to 300° C.

8. The thermal stable, one dimensional hexagonal-phase KₓV₆S_{y}Se_{8-y} nanowire of claim 7, wherein the c-axis-aligned hexagonal channels have diameters in a range of 5Å to 1 0Å.

9. The thermal stable, one dimensional hexagonal-phase KₓV₆S_{y}Se_{8-y} nanowire of claim 7, wherein the thermal stable, one dimensional hexagonal-phase KₓV₆S_{y}Se_{8-y} nanowire functions as effective van der Waals contacts for MoS₂-based field-effect transistors, with good ohmic contact, large charge mobility, and reduced Fermi-level pinning effect.

10. The thermal stable, one dimensional hexagonal-phase KₓV₆S_{y}Se_{8-y} nanowire of claim 7, wherein the KₓV₆S_{y}Se_{8-y} nanowire is K_{0.68}V₆S_{7.02}Se_{0.98}, exhibiting five distinctive Raman peaks recorded at 532 nm, comprising 165.2, 221.3, 328.4, 337.9, and 375.7 cm⁻¹, respectively.

11. The thermal stable, one dimensional hexagonal-phase KₓV₆S_{y}Se_{8-y} nanowire of claim 7, wherein the KₓV₆S_{y}Se_{8-y} nanowire is K_{1.34}V₆S_{6.79}Se_{1.21}, exhibiting five distinctive Raman peaks recorded at 532 nm, comprising 157.5, 213.6, 328.4, 337.9, and 370.1 cm⁻¹, respectively.

12. A salt-assisted method for synthesizing one-dimensional hexagonal-phase vanadium sulfide nanowires on a substrate, comprising the steps of:
preparing a substrate;
providing a precursor by mixing vanadium (V) and sulfur (S) compounds;
introducing a metal salt to the precursor via a chemical vapor deposition (SA-CVD) method to obtained a mixture;
transferring the mixture to a quartz boat and covering two pieces of fresh-cleaved fluorophlogopite mica substrates on top of loaded mixture;
transferring the quartz boat to the center of a quartz tube, and then introducing Ar and H₂ to provide an optimal synthesis atmosphere;
heating the quartz tube and then cooling the quartz boat down to room temperature; and
growing the one dimensional hexagonal-phase MₓV₆S₈ nanowires and KₓV₆S_{y}Se_{8-y} nanowires on the substrate.

13. The method of claim 12, wherein the ratio between the precursor and the metal salt is in a range of 1:1 to 1:1.5.

14. The method of claim 12, wherein step of providing a precursor comprises mixing V₂S₃ powders and S powders.

15. The method of claim 12, wherein the substrate comprises a mica substrate.

16. The method of claim 12, wherein the metal salt is selected from the group consisting of KCl, K₂S, K₂CO₃, KHCO₃, K₂C₂O₄·H₂O, Rb₂CO₃, and Cs₂CO₃.

17. The method of claim 12, wherein the quartz tube is purged with 500 s.c.c.m for 20 minutes in advance to remove internal air and moisture.

18. The method of claim 12, wherein the flow rate ratio between the Ar and H₂ is 4:1.

19. The method of claim 12, wherein the precursor further comprises Selenium (Se) compounds.
